(19) United States
(12) Patent Application Publication
(10) Pub. No.: US 2023/0251408 A1
(43) Pub. Date: Aug. 10, 2023

(54) OPTICAL FILTER, AND IMAGE SENSOR AND ELECTRONIC DEVICE INCLUDING OPTICAL FILTER

(71) Applicant: SAMSUNG ELECTRONICS CO., LTD., Suwon-si (KR)

(72) Inventors: Hyochul KIM, Yongin-si (KR); Moonsook Lee, Seoul (KR); Younggeun ROH, Seoul (KR)

(73) Assignee: SAMSUNG ELECTRONICS CO., LTD., Suwon-si (KR)

(21) Appl. No.: 17/884,740

(22) Filed: Aug. 10, 2022

(30) Foreign Application Priority Data
Oct. 28, 2021 (KR) 10-2021-0146060

(51) Int. Cl. G02B 5/20; G02B 5/30

(52) U.S. Cl. CPC G02B 5/201; G02B 5/3058; G02B 5/28

(57) ABSTRACT

Provided is an optical filter including a spectral filter, and a polarizing filter provided on the same plane as the spectral filter, wherein the spectral filter includes a plurality of spectral unit filters having different central wavelengths, and wherein the polarizing filter includes a plurality of polarization unit filters having different central wavelengths.

### CROSS-REFERENCE TO RELATED APPLICATION

This application is based on and claims priority to Korean Patent Application No. 10-2021-0146060, filed on Oct. 28, 2021, in the Korean Intellectual Property Office, the disclosure of which is incorporated by reference herein in its entirety.

### BACKGROUND

### 1. Field

Example embodiments of the present disclosure relate to methods and apparatuses for an optical filter, and an image sensor and an electronic device including the optical filter.

### 2. Description of Related Art

Image sensors using optical filters are one of the significant optical instruments in the optical field. Existing image sensors include various types of optical elements, and thus are voluminous and heavy. Recently, in response to the demand for miniaturization of image sensors, studies for simultaneously implementing integrated circuits and optical elements on one semiconductor chip have been conducted.

### SUMMARY

One or more example embodiments provide methods and apparatuses for an optical filter, and an image sensor and an electronic device including the optical filter.

Additional aspects will be set forth in part in the description which follows and, in part, will be apparent from the description, or may be learned by practice of example embodiments of the disclosure.

According to an aspect of an example embodiment, there is provided an optical filter including a spectral filter, and a polarizing filter provided on the same plane as the spectral filter, wherein the spectral filter includes a plurality of spectral unit filters having different central wavelengths, and wherein the polarizing filter includes a plurality of polarization unit filters having different central wavelengths.

The spectral filter may include four or more spectral unit filters having different central wavelengths.

The spectral unit filters may each include a lower metal reflector, a first cavity provided on the lower metal reflector, and an upper metal reflector provided on the first cavity.

An effective refractive index or a thickness of the first cavity may be adjusted based on the central wavelength of each of the spectral unit filters.

The spectral unit filters may each further include a lower dielectric layer provided on the lower metal reflector.

The spectral unit filters may each further include an upper dielectric layer provided on the upper metal reflector.

An effective refractive index or a thickness of the lower dielectric layer and the upper dielectric layer may be adjusted based on the central wavelength of each of the spectral unit filters.

The polarization unit filters may each include the lower metal reflector, a second cavity provided on the lower metal reflector, and a polarizer provided on the second cavity.

The polarization unit filters may each further include the lower dielectric layer provided on the lower metal reflector.

The polarizer may include a metal grid.

The upper metal reflector may include a metal pattern having the same thickness as the metal grid.

The spectral unit filters may each include a lower Bragg reflective layer, a first cavity provided on the lower Bragg reflective layer, and an upper Bragg reflective layer provided on the first cavity.

The polarization unit filters may each include the lower Bragg reflective layer, a second cavity provided on the lower Bragg reflective layer, and a polarizer provided on the second cavity.

The polarizer may include a metal grid.

The spectral unit filters may each include a Bragg reflective layer, a first cavity provided on the Bragg reflective layer, and a metal reflector provided on the first cavity, and the polarization unit filters may each include the Bragg reflective layer, a second cavity provided on the Bragg reflective layer, and a polarizer provided on the second cavity.

The metal reflector may include a metal pattern, and the polarizer may include a metal grid.

The metal reflector and the polarizer may have the same thickness.

The optical filter may further include a reference filter provided on the same plane as the spectral filter and the polarizing filter.

The reference filter may include at least one of a blank filter and a dark filter.

According to another aspect of an example embodiment, there is provided an optical filter including a plurality of unit filters provided on the same plane and having different central wavelengths, wherein each of the plurality of unit filters include a metal reflector, a cavity provided on the metal reflector, and a polarizer provided on the cavity.

The polarizer may include a metal grid.

According to another aspect of an example embodiment, there is provided an optical filter including a plurality of unit filters provided on the same plane and having different central wavelengths, wherein each of the plurality of unit filters includes a Bragg reflective layer, a cavity provided on the Bragg reflective layer, and a polarizer provided on the cavity.

The polarizer may include a metal grid.

According to another aspect of an example embodiment, there is provided an image sensor including a pixel array including a plurality of pixels, and an optical filter provided on the pixel array.

The image sensor may further include a single imaging lens provided above the optical filter.

The image sensor may further include a timing controller, a row decoder, and an output circuit.

According to another aspect of an example embodiment, there is provided an electronic device including an image sensor including a pixel array including a plurality of pixels, and an optical filter provided on the pixel array, wherein the optical filter includes a spectral filter, and a polarizing filter provided on the same plane as the spectral filter, wherein the spectral filter includes a plurality of spectral unit filters having different central wavelengths, and wherein the polarizing filter includes a plurality of polarization unit filters having different central wavelengths.

The electronic device may include a mobile phone, a smart phone, a tablet, a smart tablet, a digital camera, a camcorder, a notebook computer, a television, a smart television, a smart refrigerator, a security camera, a robot, or a medical camera.

### BRIEF DESCRIPTION OF THE DRAWINGS

The above and/or other aspects, features, and advantages of example embodiments of the disclosure will be more apparent from the following description taken in conjunction with the accompanying drawings, in which:

FIG. 1 is a block diagram of an image sensor according to an example embodiment;

FIG. 2 is a plan view of an optical filter shown in FIG. 1, according to an example embodiment;

FIG. 3 is a cross-sectional view taken along line A-A′ of FIG. 2;

FIG. 4 is a plan view illustrating an example of a polarizer shown in FIG. 3;

FIG. 5A illustrates an example of a transmission spectrum for a spectral unit filter shown in FIG. 3;

FIG. 5B illustrates an example of a transmission spectrum for a polarization unit filter shown in FIG. 3;

FIG. 6 is a cross-sectional view illustrating an optical filter according to another example embodiment;

FIG. 7 is a cross-sectional view illustrating an optical filter according to another example embodiment;

FIG. 8 is a cross-sectional view illustrating an optical filter according to another example embodiment;

FIG. 9 is a cross-sectional view illustrating an optical filter according to another example embodiment;

FIGS. 10A and 10B are plan views illustrating examples of an upper reflector shown in FIG. 9;

FIG. 11 is a plan view illustrating an example of a polarizer shown in FIG. 9;

FIG. 12 is a cross-sectional view illustrating an optical filter according to another example embodiment;

FIG. 13 is a plan view illustrating an optical filter according to another example embodiment;

FIG. 14 is a plan view illustrating an optical filter according to another example embodiment;

FIG. 15 is a cross-sectional view taken along line B-B′ of FIG. 14;

FIG. 16 is a cross-sectional view illustrating an optical filter according to another example embodiment;

FIG. 17 is a plan view of an example of an optical filter that may be applied to the image sensor of FIG. 1;

FIG. 18 illustrates an image sensor according to another example embodiment;

FIG. 19 is a block diagram illustrating an electronic device including an image sensor, according to example embodiments;

FIG. 20 is a block diagram illustrating a camera module of FIG. 19; and

FIGS. 21 through 30 are diagrams illustrating various examples of electronic devices having image sensors applied thereto, according to example embodiments.

### DETAILED DESCRIPTION

Reference will now be made in detail to embodiments, examples of which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, example embodiments will be described in detail with reference to the accompanying drawings. Like reference numerals in the drawings denote like elements, and the size of each element in the drawings may be exaggerated for clarity and convenience of description. Example embodiments described below are merely examples, and various modifications may be made from these example embodiments.

Hereinafter, what is described as “above” or “on” may include those directly on, underneath, left, and right in contact, as well as above, below, left, and right in non-contact. The singular forms are intended to include the plural forms as well, unless the context clearly indicates otherwise. Also, when a part “includes” any element, it means that the part may further include other elements, rather than excluding other elements, unless otherwise stated.

The term “the” and the similar indicative terms may be used in both the singular and the plural. If there is no explicit description of the order of steps constituting a method or no contrary description thereto, these steps may be performed in an appropriate order, and are not limited to the order described.

In addition, the terms “... unit”, “module”, etc. described herein mean a unit that processes at least one function or operation, may be implemented as hardware or software, or may be implemented as a combination of hardware and software.

Connections of lines or connection members between elements shown in the drawings are illustrative of functional connections and/or physical or circuitry connections, and may be replaced in an actual device, or may be represented as additional various functional connections, physical connections, or circuitry connections.

The use of all examples or example terms is merely for describing the technical concept in detail, and the scope thereof is not limited by these examples or example terms unless limited by claims.

An image sensor may not clearly image an object when reflected light reflected from moisture or a glass surface within the field of view (FOV) is highly scattered. In addition, when background light includes a complex multi-component light source, the image sensor may not image an actual color due to a background light component reflected from the object. A high-resolution RGB image sensor has a limitation in implementing the clarity and color accuracy of such image quality. Therefore, there is a need for an image sensor having a polarization function for clearly imaging an object even in the presence of moisture, a glass surface, or the like within the field of view and a spectral function for imaging complex wavelength components of background light, flicker characteristics, the position of a light source, and the like.

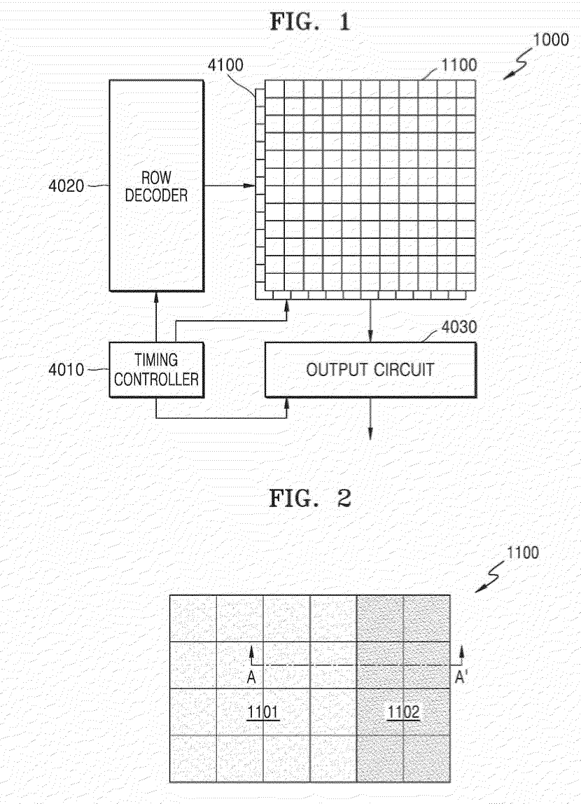

FIG. 1 is a block diagram of an image sensor 1000 according to an example embodiment.

Referring to FIG. 1, the image sensor 1000 may include an optical filter 1100, a pixel array 4100, a timing controller 4010, a row decoder 4020, and an output circuit 4030. The image sensor 1000 may include a charge-coupled device (CCD) image sensor or a complementary metal oxide semiconductor (CMOS) image sensor, but is not limited thereto.

The optical filter 1100 transmits light having different wavelength regions, and includes a plurality of unit filters arranged two-dimensionally. The pixel array 4100 includes a plurality of pixels detecting light having different wavelengths, passing through the optical filter 1100. In detail, the pixel array 4100 includes pixels arranged two-dimensionally along a plurality of rows and a plurality of columns. The row decoder 4020 selects one of rows of the pixel array 4100 in response to a row address signal output from the timing controller 4010. The output circuit 4030 outputs, in a column unit, a light detection signal from a plurality of pixels arranged along the selected row. Accordingly, the output circuit 4030 may include a column decoder and an analog-to-digital converter (ADC). For example, the output circuit 4030 may include a plurality of ADCs arranged for respective columns between the column decoder and the pixel array 4100, or one ADC arranged at an output terminal of the column decoder. The timing controller 4010, the row decoder 4020, and the output circuit 4030 may be implemented as a single chip or respectively separate chips. A processor for processing an image signal output via the output circuit 4030 may be implemented as a single chip together with the timing controller 4010, the row decoder 4020, and the output circuit 4030. The pixel array 4100 includes a plurality of pixels detecting light having different wavelengths. Here, the arrangement of the pixels may be implemented in various ways.

Hereinafter, the optical filter 1100 of the image sensor 1000 will be described in detail. FIG. 2 is a plan view of an optical filter according to an example embodiment.

An optical filter 1100 shown in FIG. 2 includes a spectral filter 1101 and a polarizing filter 1102 which are provided on the same plane, for example, an upper surface of the pixel array 4100. The spectral filter 1101 performs a spectral function, and may include a plurality of spectral unit filters having different central wavelengths. The polarizing filter 1102 performs a polarization function and a spectral function, and may include a plurality of polarization unit filters having different central wavelengths.

The plurality of spectral unit filters and the plurality of polarization unit filters may be arranged in a two-dimensional form. The spectral filter 1101 may include four or more spectral unit filters having different central wavelengths. FIG. 2 illustrates an example of a spectral filter including 16 spectral unit filters having different central wavelengths. Also, FIG. 2 illustrates an example of a polarizing filter including 8 polarization unit filters having different central wavelengths.

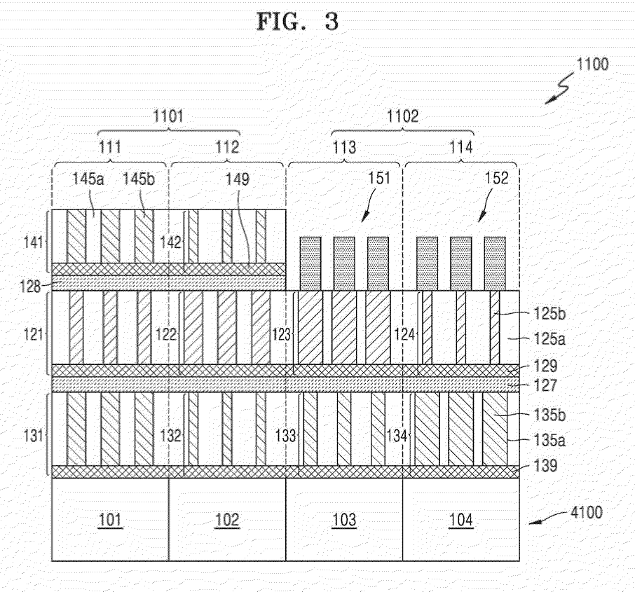

FIG. 3 is a cross-sectional view of the optical filter 1100 taken along line A-A′ of FIG. 2. FIG. 3 illustrates two spectral unit filters including, for example, a first spectral unit filter 111 and a second spectral unit filter 112, and two polarization unit filters including, for example, a first polarization unit filter 113 and a second polarization unit filter 114.

Referring to FIG. 3, the first and second spectral unit filters 111 and 112, and the first and second polarization unit filters 113 and 114 are arranged on the upper surface of the pixel array 4100. A first pixel 101, a second pixel 102, a third pixel 103, and a fourth pixel 104 are provided below the first and second spectral unit filters 111 and 112, and the first and second polarization unit filters 113 and 114.

The first and second spectral unit filters 111 and 112 included in the spectral filter 1101 may have different central wavelengths. The first and second spectral unit filters 111 and 112 may include resonators having a Fabry-Perot structure. The first and second spectral unit filters 111 and 112 include a lower metal reflector 127, first cavities 121 and 122 provided on the lower metal reflector 127, and an upper metal reflector 128 provided on the first cavities 121 and 122 opposite to the lower metal reflector 127.

When light passes through the upper metal reflector 128 and is incident on the first cavities 121 and 122, the light reciprocates inside the first cavities 121 and 122, between the lower and upper metal reflectors 127 and 128, and causes constructive interference and destructive interference in this process. In addition, light having a particular central wavelength satisfying a constructive interference condition in the first cavities 121 and 122 passes through the lower metal reflector 127 and is incident on the first and second pixels 101 and 102 of the pixel array 4100.

The lower and upper metal reflectors 127 and 128 may include a metal material capable of reflecting light having a certain wavelength region. The lower and upper metal reflectors 127 and 128 may each include, for example, aluminum (Al), silver (Ag), gold (Au), copper (Cu), titanium nitride (TiN), or the like, but embodiments are not limited thereto. The lower and upper metal reflectors 127 and 128 may include the same type of metal material, but are not limited thereto.

The first cavities 121 and 122 are provided between the lower and upper metal reflectors 127 and 128. The first cavities 121 and 122 may be formed to have the same thickness. Central wavelengths of the first and second spectral unit filters 111 and 112 may be determined by adjusting an effective refractive index of the first cavities 121 and 122. The first cavities 121 and 122 may each include a first dielectric 125a, and a second dielectric 125b periodically arranged within the first dielectric 125a to form a pattern. The second dielectric 125b may have a different refractive index than the first dielectric 125a.

The first and second dielectrics 125a and 125b may each include, for example, silicon, silicon oxide, silicon nitride, titanium oxide, or the like. As a detailed example, the first dielectric 125a may include silicon oxide, and the second dielectric 125b may include titanium oxide. However, embodiments are not limited thereto. The effective refractive index of the first cavities 121 and 122 may be adjusted by changing a shape and/or size of the second dielectric 125b, and accordingly, central wavelengths of the first and second spectral unit filters 111 and 112 may be determined.

An etch stop layer 129 may be further provided on lower surfaces of the first cavities 121 and 122. The etch stop layer 129 may be provided between the lower surfaces of the first cavities and the lower metal reflector 127. The etch stop layer 129 further facilitates a patterning process for forming the first cavities 121 and 122. The etch stop layer 129 may include, for example, silicon oxide, titanium oxide, hafnium oxide, or the like, but is not limited thereto.

A lower dielectric layer may be further provided between the lower metal reflector 127 and the pixel array 4100. The lower dielectric layer may be provided to improve transmittance of the first and second spectral unit filters 111 and 112. The lower dielectric layer may include first lower patterned films 131 and 132 provided to correspond to different central wavelengths. The first lower patterned films 131 and 132 may be formed to have the same thickness.

The first lower patterned films 131 and 132 may be provided to have an effective refractive index corresponding to the central wavelengths of the first and second spectral unit filters 111 and 112. The first lower patterned films 131 and 132 may each include a third dielectric 135a, and a fourth dielectric 135b periodically arranged within the third dielectric 135a to form a pattern. The fourth dielectric 135b may have a different refractive index than the third dielectric 135a. The third and fourth dielectrics 135a and 135b may each include, for example, titanium oxide, silicon nitride, hafnium oxide, silicon oxide, high refractive polymer, or the like, but are not limited thereto. An effective refractive index of the first lower patterned films 131 and 132 may be adjusted by changing a shape and/or size of the fourth dielectric 135b.

An etch stop layer 139 may be further provided on lower surfaces of the first lower patterned films 131 and 132. The etch stop layer 139 further facilitates a patterning process for forming the first lower patterned films 131 and 132. The etch stop layer 139 may include, for example, silicon oxide, titanium oxide, hafnium oxide, or the like, but is not limited thereto.

An upper dielectric layer may be further provided on an upper surface of the upper metal reflector 128. Similar to the lower dielectric layer, the upper dielectric layer may be provided to improve the transmittance of the first and second spectral unit filters 111 and 112. The upper dielectric layer may include upper patterned films 141 and 142 provided to correspond to different central wavelengths. The upper patterned films 141 and 142 may be formed to have the same thickness.

The upper patterned films 141 and 142 may be provided to have an effective refractive index corresponding to the central wavelengths of the first and second spectral unit filters 111 and 112. The upper patterned films 141 and 142 may each include a fifth dielectric 145a, and a sixth dielectric 145b periodically arranged within the fifth dielectric 145a to form a pattern. The sixth dielectric 145b may have a different refractive index than the fifth dielectric 145a. The fifth and sixth dielectrics 145a and 145b may each include, for example, titanium oxide, silicon nitride, hafnium oxide, silicon oxide, high refractive polymer, or the like, but are not limited thereto. The effective refractive index of the upper patterned films 141 and 142 may be adjusted by changing a shape and/or size of the sixth dielectric 145b.

An etch stop layer 149 may be further provided on lower surfaces of the upper patterned films 141 and 142. The etch stop layer 149 may be provided between the lower surfaces of the upper patterned films 141 and 142 and the upper metal reflector. The etch stop layer 149 further facilitates a patterning process for forming the upper patterned films 141 and 142. The etch stop layer 149 may include, for example, silicon oxide, titanium oxide, hafnium oxide, or the like, but is not limited thereto.

The first and second polarization unit filters 113 and 114 constituting the polarizing filter 1102 may have different central wavelengths. The first and second polarization unit filters 113 and 114 include the lower metal reflector 127 described above, second cavities 123 and 124 provided on the lower metal reflector 127, and polarizers 151 and 152 provided on the second cavities 123 and 123.

The second cavities 123 and 124 are provided on the upper surface of the lower metal reflector 127. The second cavities 123 and 124 may be formed to have the same thickness as the first cavities 121 and 122 described above. Central wavelengths of the first and second polarization unit filters 113 and 114 may be determined by adjusting an effective refractive index of the second cavities 123 and 124. Similar to the first cavities 121 and 122, the second cavities 123 and 124 may include the first dielectric 125a, and the second dielectric 125b periodically arranged within the first dielectric 125a to form a pattern. The etch stop layer 129 may be further provided on lower surfaces of the second cavities 123 and 124.

The polarizers 151 and 152 are provided on upper surfaces of the second cavities 123 and 124. The polarizers 151 and 152 may each transmit only light having a particular polarization (e.g., a vertical polarization or a horizontal polarization) from among external incident light. In addition, like the upper metal reflector 128 described above, the polarizers 151 and 152 may reflect light having a certain wavelength region.

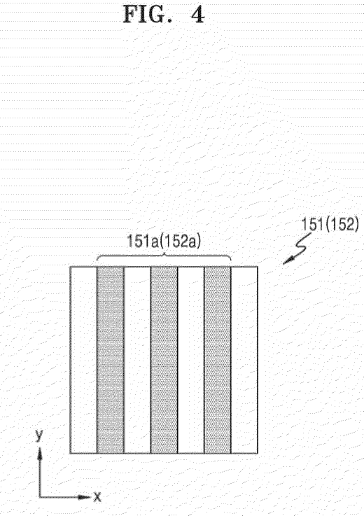

FIG. 4 illustrates planes of polarizers 151 and 152. Referring to FIG. 4, the polarizers 151 and 152 may respectively include metal grids 151a and 152a. The metal grids 151a and 152a may have a shape in which linear patterns extending in a certain direction (e.g., a y-axis direction) are arranged at certain intervals. For example, air or other transparent dielectric material may be provided between the linear patterns. A pitch between the linear patterns or a material filled between the linear patterns may vary with central wavelengths of the first and second polarization unit filters 113 and 114. The metal grids 151a and 152a may include a certain metal material. For example, in a central wavelength region of a visible light region, the metal grids 151a and 152a may include Al grids. However, the metal grids 151a and 152a are not limited thereto.

As light passes through the polarizers 151 and 152, only light having a particular polarization is incident on the second cavities 123 and 124. In addition, the light having the particular polarization reciprocates inside the second cavities 123 and 124, between the lower metal reflector 127 and the polarizers 151 and 152, and then, light having a particular central wavelength satisfying a constructive interference condition passes through the lower metal reflector 127. The light having the particular polarization and the particular central wavelength, passing through the lower metal reflector 127 is incident on the third and fourth pixels 103 and 104 of the pixel array 4100.

The lower dielectric layer may be further provided between the lower metal reflector 127 and the pixel array 4100. The lower dielectric layer may include second lower patterned films 133 and 134 provided to correspond to different central wavelengths. The second lower patterned films 133 and 134 may be formed to have the same thickness as the first lower patterned films 131 and 132 described above. The second lower patterned films 133 and 134 may have an effective refractive index corresponding to central wavelengths of the first and second polarization unit filters 113 and 114. The second lower patterned films 133 and 134 may each include the third dielectric 135a, and the fourth dielectric 135b periodically arranged within the third dielectric 135a to form a pattern. The etch stop layer 139 may be further provided on lower surfaces of the second lower patterned films 133 and 134.

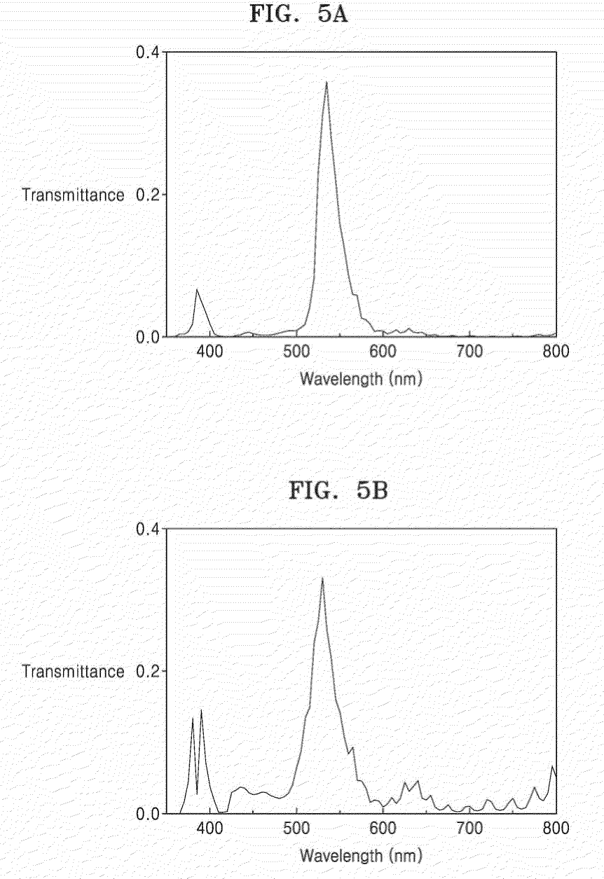

FIG. 5A illustrates an example of a transmission spectrum for a spectral unit filter having a central wavelength of 540 nm from among the first and second spectral unit filters 111 and 112 shown in FIG. 3. In addition, FIG. 5B illustrates an example of a transmission spectrum for a polarization unit filter having a central wavelength of 540 nm from among the first and second polarization unit filters 113 and 114 shown in FIG. 3. FIG. 5B illustrates a transmission spectrum of light having a polarization perpendicular to a metal grid (a polarizer), and light having a polarization parallel to the metal grid is mostly blocked.

As described above, the optical filter 1100 includes the spectral filter 1101 including a plurality of spectral unit filters including, for example, the first and second spectral unit filters 111 and 112 having different central wavelengths, and the polarizing filter 1102 including a plurality of polarization unit filters including, for example, the first and second polarization unit filters 113 and 114 having different central wavelengths. For example, the spectral filter 1101 may perform a spectral function, and the polarizing filter 1102 may perform a polarization function and a spectral function, thereby implementing the image sensor 1000 configured to obtain both a spectral image and a polarized image.

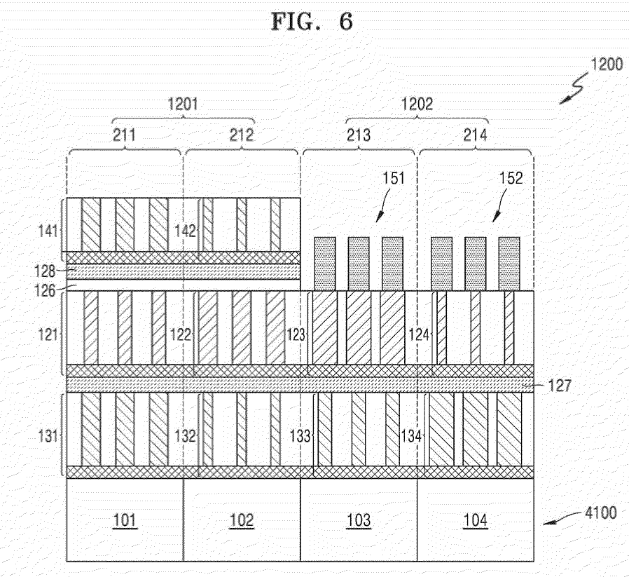

FIG. 6 is a cross-sectional view illustrating an optical filter 1200 according to another example embodiment. The optical filter 1200 shown in FIG. 6 is the same as the optical filter 1100 shown in FIG. 3, except that a first spectral unit filter 211 and a second spectral unit filter 212 include a spacer 126. Hereinafter, differences thereof will be mainly described.

Referring to FIG. 6, the optical filter 1200 includes a spectral filter 1201 including the first and second spectral unit filters 211 and 212, and a polarizing filter 1202 including first and second polarization unit filters 213 and 214. For example, the first and second spectral unit filters 211 and 212 further include the spacer 126 provided between the upper surfaces of the first cavities 121 and 122 and an upper metal reflector 128.

The first cavities 121 and 122 may have a multi-mode structure having a plurality of central wavelengths. In this case, in the multi-mode structure of the first cavities 121 and 122, a central wavelength of a secondary mode may be used as a central wavelength of each of the first and second spectral unit filters 211 and 212 by the spacer 126. The spacer 126 may include, for example, silicon oxide, titanium oxide, silicon nitride, or the like, but this is merely an example. In the above description, both the first and second spectral unit filters 211 and 212 include the spacer 126, but only some of the first and second spectral unit filters 211 and 212 may include the spacer 126.

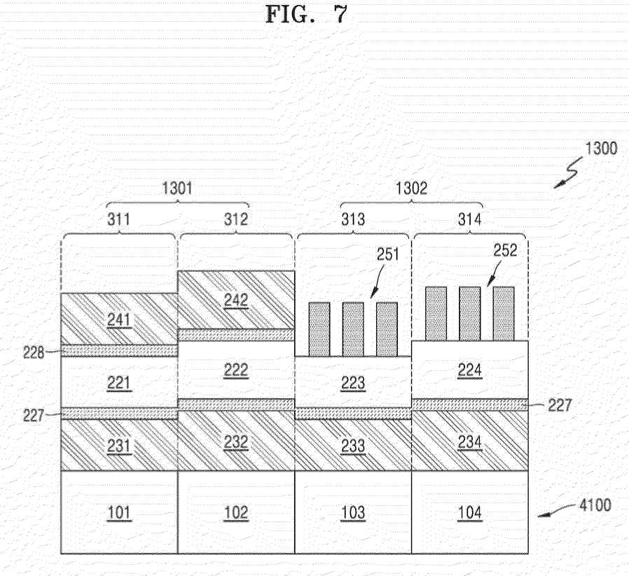

FIG. 7 is a cross-sectional view illustrating an optical filter 1300 according to another example embodiment. Hereinafter, differences than the embodiments described above will be mainly described.

Referring to FIG. 7, the optical filter 1300 includes a spectral filter 1301 including a first spectral unit filter 311 and a second spectral unit filter 312, and a polarizing filter 1302 including a first polarization unit filter 313 and a second polarization unit filter 314. The first and second spectral unit filters 311 and 312 include a lower metal reflector 227, first cavities 221 and 222 provided on the lower metal reflector 227, and an upper metal reflector 228 provided on the first cavities 221 and 222. For example, the first cavities 221 and 222 may include silicon, silicon oxide, or titanium oxide. A thickness of the first cavities 221 and 222 may be adjusted according to central wavelengths of the first and second spectral unit filters 311 and 312.

A lower dielectric layer may be further provided between the lower metal reflector 227 and a pixel array 4100. The lower dielectric layer may be provided to improve transmittance of the first and second spectral unit filters 311 and 312. The lower dielectric layer may include first lower dielectric layers 231 and 232, and a thickness of the first lower dielectric layers 231 and 232 may be adjusted according to the central wavelengths of the first and second spectral unit filters 311 and 312.

An upper dielectric layer may be further provided on an upper surface of the upper metal reflector 228. Similar to the lower dielectric layer, the upper dielectric layer may be provided to improve the transmittance of the first and second spectral unit filters 311 and 312. The upper dielectric layer may include upper dielectric layers 241 and 242, and a thickness of the upper dielectric layers 241 and 242 may be adjusted according to the central wavelengths of the first and second spectral unit filters 311 and 312.

The first and second polarization unit filters 313 and 314 include the lower metal reflector 227, second cavities 223 and 224 provided on the lower metal reflector 227, and polarizers 251 and 252 provided on the second cavities 223 and 224. A thickness of the second cavities 223 and 224 may be adjusted according to central wavelengths of the first and second polarization unit filters 313 and 314. The polarizers 251 and 252 are as described above, and thus, a description thereof will be omitted herein.

The lower dielectric layer may be further provided between the lower metal reflector 227 and the pixel array 4100. The lower dielectric layer may include second lower dielectric layers 233 and 234 provided such that a thickness thereof is adjusted according to the central wavelengths of the first and second polarization unit filters 313 and 314.

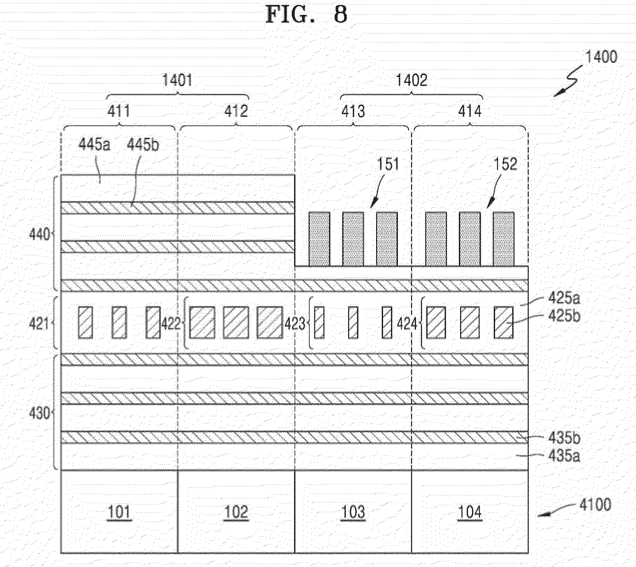

FIG. 8 is a cross-sectional view illustrating an optical filter 1400 according to another example embodiment.

Referring to FIG. 8, the optical filter 1400 includes a spectral filter 1401 including a first spectral unit filter 411 and a second spectral unit filter 412, and a polarizing filter 1402 including a first polarization unit filter 413 and a second polarization unit filter 414. The first and second spectral unit filters 411 and 412 may include resonators having a Fabry-Perot structure. The first and second spectral unit filters 411 and 412 include a lower Bragg reflective layer 430, first cavities 421 and 422 provided on the lower Bragg reflective layer 430, and an upper Bragg reflective layer 440 provided on the first cavities 421 and 422. The lower and upper Bragg reflective layers 430 and 440 may each be a distributed Bragg reflector (DBR).

The lower Bragg reflective layer 430 may have a structure in which a first material layer 435a and a second material layer 435b having different refractive indexes are alternately stacked. For example, the first and second material layers 435a and 435b may include silicon oxide and titanium oxide. For another example, the first and second material layers 435a and 435b may include silicon oxide and silicon. However, the first and second material layers 435a and 435b are not limited thereto.

The upper Bragg reflective layer 440 may have a structure in which a third material layer 445a and a fourth material layer 445b having different refractive indexes are alternately stacked. The third and fourth material layers 445a and 445b may include the same materials as the first and second material layers 435a and 435b, but are not limited thereto.

The first cavities 421 and 422 are provided between the lower and upper Bragg reflective layers 430 and 440. The first cavities 421 and 422 may be formed to have the same thickness. Central wavelengths of the first and second spectral unit filters 411 and 412 may be determined by adjusting an effective refractive index of the first cavities 421 and 422. The first cavities 421 and 422 may each include a first dielectric 425a, and a second dielectric 425b periodically arranged within the first dielectric 425a to form a pattern. The second dielectric 425b may have a different refractive index than the first dielectric 425a. The effective refractive index of the first cavities 421 and 422 may be adjusted by changing a shape and/or size of the second dielectric 425b. An etch stop layer may be further provided on lower surfaces of the first cavities 421 and 422.

The first and second polarization unit filters 413 and 414 include the lower Bragg reflective layer 430, second cavities 423 and 424 provided on the lower Bragg reflective layer 430, and polarizers 151 and 152 provided on the second cavities 423 and 424. The lower Bragg reflective layer 430 and the polarizers 151 and 152 are as described above, and thus, a description thereof will be omitted herein.

The second cavities 423 and 424 are provided on an upper surface of the lower Bragg reflective layer 430. The second cavities 423 and 424 may be formed to have the same thickness as the first cavities 421 and 422. Central wavelengths of the first and second polarization unit filters 413 and 414 may be determined by adjusting an effective refractive index of the second cavities 423 and 424. Similar to the first cavities 421 and 422, the second cavities 423 and 424 may each include the first dielectric 425a, and the second dielectric 425b periodically arranged within the first dielectric 425a to form a pattern. The effective refractive index of the second cavities 423 and 424 may be adjusted by changing a shape and/or size of the second dielectric 425b.

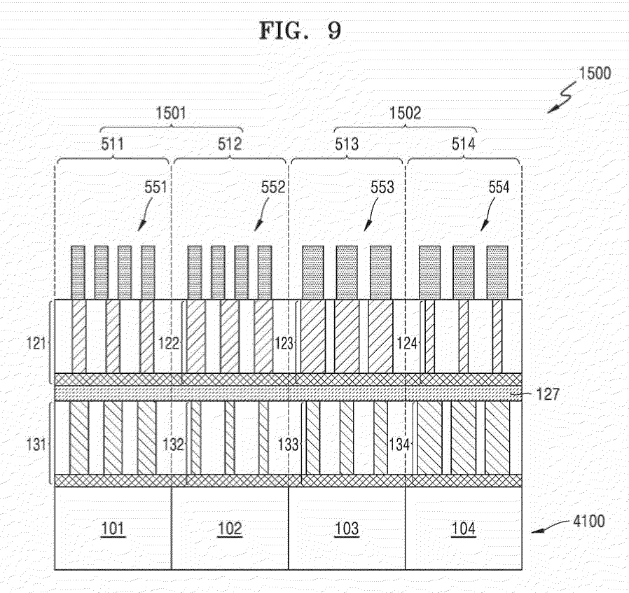

FIG. 9 is a cross-sectional view illustrating an optical filter 1500 according to another example embodiment.

Referring to FIG. 9, the optical filter 1500 includes a spectral filter 1501 including a first spectral unit filter 511 and a second spectral unit filter 512, and a polarizing filter 1502 including a first polarization unit filter 513 and a second polarization unit filter 514.

The first and second spectral unit filters 511 and 512 include a lower metal reflector 127, first cavities 121 and 122 provided on the lower metal reflector 127, and upper metal reflectors 551 and 552 provided on the first cavities 121 and 122.

The lower metal reflector 127 is as described above, and thus, a description thereof will be omitted herein. The first cavities 121 and 122 may be formed to have the same thickness. In this case, the first cavities 121 and 122 may be provided such that an effective refractive index thereof is adjusted according to central wavelengths of the first and second spectral unit filters 511 and 512. The first cavities 121 and 122 may be provided such that a thickness thereof is adjusted.

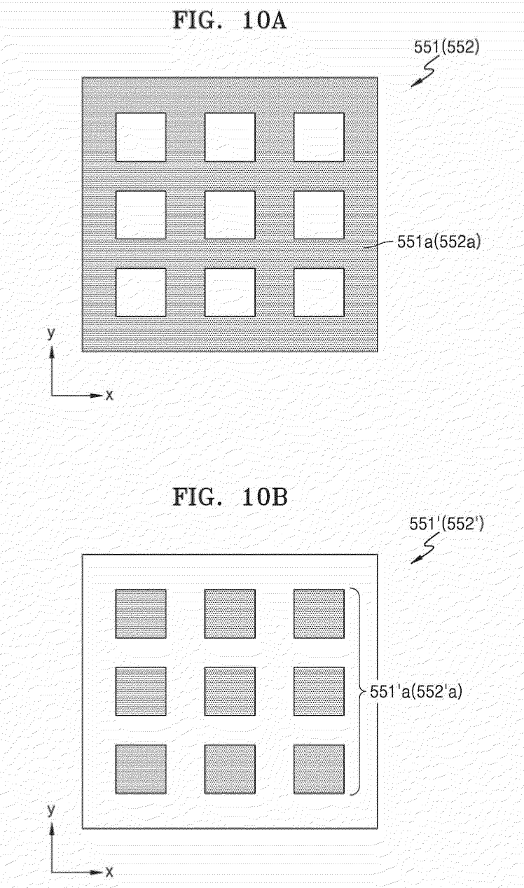

The upper metal reflectors 551 and 552 are provided on upper surfaces of the first cavities 121 and 122. For example, similar to the lower metal reflector 127, the upper metal reflectors 551 and 552 may reflect light having a certain wavelength region. FIG. 10A illustrates planes of upper metal reflectors 551 and 552. Referring to FIG. 10A, the upper metal reflectors 551 and 552 may include metal patterns 551a and 552a having a symmetrical shape. The metal patterns 551a and 552a may have, for example, a shape that is symmetrical with respect to X-axis and y-axis directions. FIG. 10B illustrates planes of upper metal reflectors 551′ and 552′ including metal patterns 551′a and 552′a, according to another example embodiment. The upper metal reflectors 551′ and 552′ may include the same metal material as the lower metal reflector 127, but are not limited thereto.

A lower dielectric layer may be further provided between the lower metal reflector 127 and a pixel array 4100. The lower dielectric layer may include first lower patterned films 131 and 132 provided to correspond to different central wavelengths. The first lower patterned films 131 and 132 may be provided to have an effective refractive index corresponding to the central wavelengths of the first and second spectral unit filters 511 and 512. The lower dielectric layer may be provided such that a thickness thereof is adjusted.

The first and second polarization unit filters 513 and 514 include the lower metal reflector 227, second cavities 123 and 124 provided on the lower metal reflector 227, and polarizers 553 and 554 provided on the second cavities 123 and 124.

The second cavities 123 and 124 are provided on an upper surface of the lower metal reflector 127. The second cavities 123 and 124 may be formed to have the same thickness as the first cavities 121 and 122 described above. In this case, the second cavities 123 and 124 may be provided such that an effective refractive index thereof is adjusted according to central wavelengths of the first and second polarization unit filters 513 and 514. The second cavities 123 and 124 may be provided such that a thickness thereof is adjusted.

The polarizers 553 and 554 are provided on upper surfaces of the second cavities 123 and 124. The polarizers 553 and 554 may each transmit only light having a particular polarization from among external incident light, and may also reflect light having a certain wavelength region, similar to the upper metal reflectors 551 and 552.

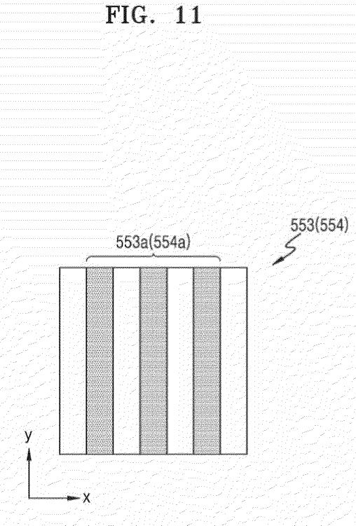

FIG. 11 illustrates planes of polarizers 553 and 554. Referring to FIG. 11, the polarizers 553 and 554 may respectively include metal grids 553a and 554a.

The polarizers 553 and 554 may be formed to have the same thickness as the upper metal reflectors 551 and 552 on the same plane. In addition, the polarizers 553 and 554 may include the same metal material as the upper metal reflectors 551 and 552. In this case, the upper metal reflectors 551 and 552 and the polarizers 553 and 554 may be simultaneously formed via a single patterning process.

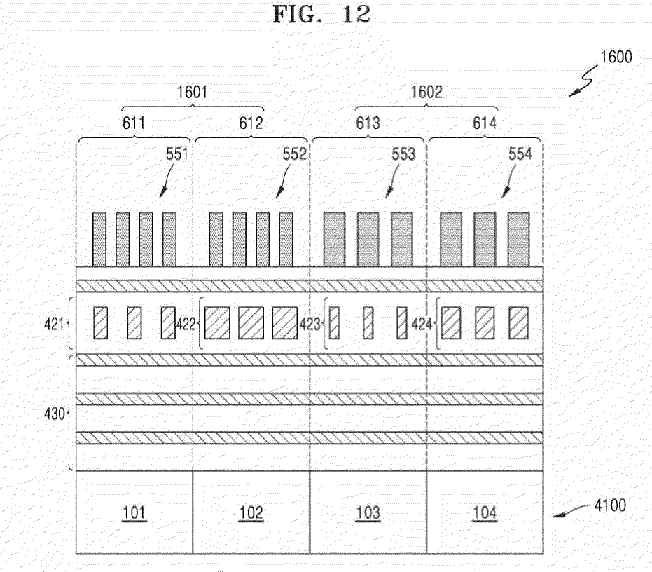

FIG. 12 is a cross-sectional view illustrating an optical filter 1600 according to another example embodiment.

Referring to FIG. 12, the optical filter 1600 includes a spectral filter 1601 including a first second spectral unit filter 611 and a second spectral unit filter 612, and a polarizing filter 1602 including a first polarization unit filter 613 and a second polarization unit filter 614. The first and second spectral unit filters 611 and 612 include a Bragg reflective layer 430, first cavities 421 and 422 provided on the Bragg reflective layer 430, and metal reflectors 551 and 552 provided on the first cavities 421 and 422. The Bragg reflective layer 430 may be a distributed Bragg reflector (DBR).

The Bragg reflective layer 430 may have a structure in which first and second material layers having different refractive indexes are alternately stacked. The first cavities 421 and 422 may be formed to have the same thickness. The first cavities 421 and 422 may be provided such that an effective refractive index thereof is adjusted according to central wavelengths of the first and second spectral unit filters 611 and 612. The metal reflectors 551 and 552 are provided on upper surfaces of the first cavities 421 and 422. Here, the metal reflectors 551 and 552 are the same as the upper metal reflectors 551 and 552 including the metal patterns 551a and 552a, shown in FIG. 9.

The first and second polarization unit filters 613 and 614 include the Bragg reflective layer 430, second cavities 423 and 424 provided on the Bragg reflective layer 430, and polarizers 553 and 554 provided on the second cavities 423 and 424. The second cavities 423 and 424 may be formed to have the same thickness as the first cavities 421 and 422. The second cavities 423 and 424 may be provided such that an effective refractive index thereof is adjusted according to central wavelengths of the first and second polarization unit filters 613 and 614. The polarizers 553 and 554 are provided on upper surfaces of the second cavities 423 and 424. Here, the polarizers 553 and 554 are the same as the polarizers 553 and 554 including the metal grids 553a and 554a, shown in FIG. 9.

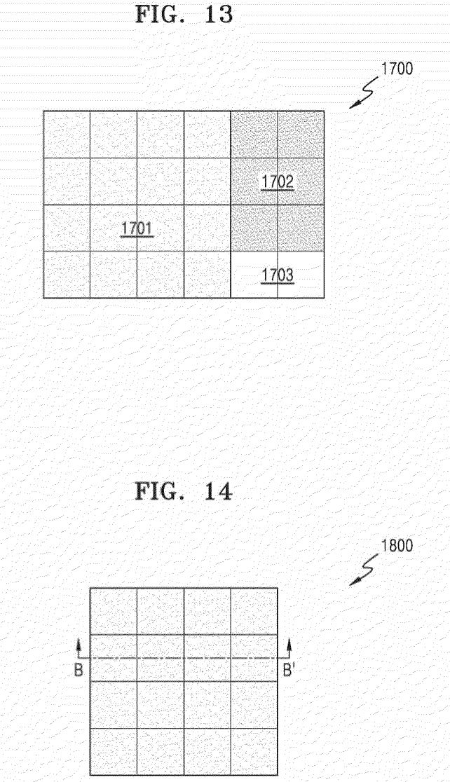

FIG. 13 is a plan view illustrating an optical filter 1700 according to another example embodiment.

Referring to FIG. 13, the optical filer 1700 includes a spectral filter 1701, a polarizing filter 1702, and a reference filter 1703 provided on the same plane, for example, on an upper surface of the pixel array 4100. The spectral filter 1701 and the polarizing filter 1702 are as described above, and thus, a description thereof will be omitted herein. The reference filter 1703 may be used to measure dark noise or to identify an actual reduction in ambient light. Accordingly, the reference filter 1703 may include a pixel (e.g., a blank pixel) that transmits a broadband wavelength and does not have spectral and polarization characteristics, and/or a dark pixel.

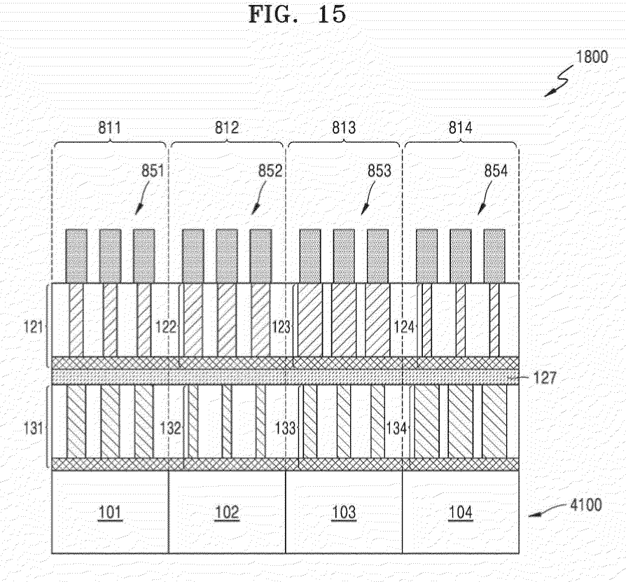

FIG. 14 is a plan view illustrating an optical filter 1800 according to another example embodiment. In addition, FIG. 15 is a cross-sectional view taken along line B-B′ of FIG. 14.

Referring to FIGS. 14 and 15, the optical filter 1800 includes a plurality of unit filters two-dimensionally arranged on an upper surface of a pixel array 4100 and having different central wavelengths. For example, each of the unit filters may be the same as a polarizing filter as described above, and may perform both a spectral function and a polarization function. FIG. 14 illustrates 16 units filters arranged in the form of a 4×4 array, and FIG. 15 illustrates cross-sections of four unit filters including, for example, a first unit filter 811, a second unit filter 812, a third unit filter 813, and a fourth unit filter 814.

The unit filters 811, 812, 813, and 814 include a metal reflector 127, cavities 121, 122, 123, and 124 provided on the metal reflector 127, and polarizers 851, 852, 853, and 854 provided on the cavities 121, 122, and 123, and 124.

The metal reflector 127 is the same as a lower metal reflector as described above. The cavities 121, 122, 123, and 124 may be formed to have the same thickness. In this case, the cavities 121, 122, 123, and 124 may be provided such that an effective refractive index thereof is adjusted according to central wavelengths of the unit filters 811, 812, 813, and 814. The cavities 121, 122, 123, and 124 may be provided such that a thickness thereof is adjusted.

The polarizers 851, 852, 853, and 854 are provided on upper surfaces of the cavities 121, 122, 123, and 124. The polarizers 851, 852, 853, and 854 may each transmit only light having a particular polarization from among external incident light, and may also reflect light having a certain wavelength region. The polarizers 851, 852, 853, and 854 are the same as polarizers as described above, and thus, a detailed description thereof will be omitted herein.

A lower dielectric layer may be further provided between the metal reflector 127 and the pixel array 4100. The lower dielectric layer may include lower patterned films 131, 132, 133, and 134 provided to correspond to different central wavelengths. The lower patterned films 131, 132, 133, and 134 may be provided to have an effective refractive index corresponding to the central wavelengths of the unit filters 811, 812, 813, and 814. The lower dielectric layer may be provided such that a thickness thereof is adjusted.

In the example embodiment, the optical filter 1800 may include the unit filters 811, 812, 813, and 814 configured to perform a spectral function and a polarization function, thereby implementing an image sensor configured to obtain a spectral image and a polarized image.

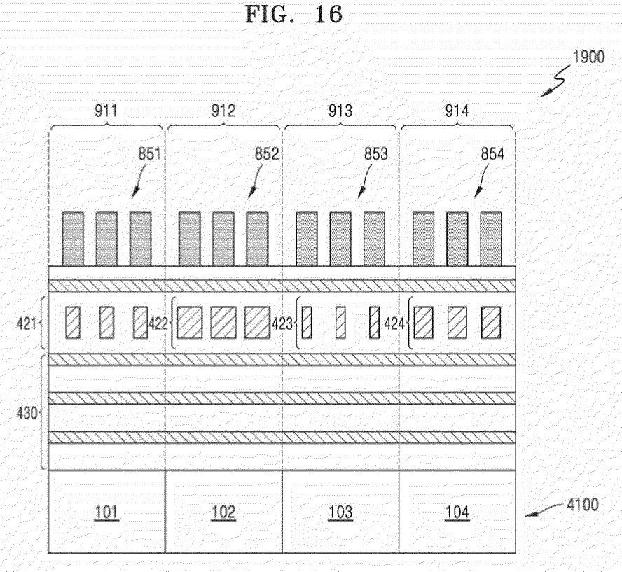

FIG. 16 is a cross-sectional view illustrating an optical filter 1900 according to another example embodiment.

Referring to FIG. 16, the optical filter 1900 includes a plurality of unit filters 911, 912, 913, and 914 having different central wavelengths. The unit filters 911, 912, 913, and 914 may each perform a spectral function and a polarization function, as described above. The unit filters 911, 912, 913, and 914 include a Bragg reflective layer 430, cavities 421, 422, 423, and 424 provided on the Bragg reflective layer 430, and polarizers 851, 852, 853, and 854 provided on the cavities 421, 422, 423, and 424.

The Bragg reflective layer 430 may have a structure in which first and second material layers having different refractive indexes are alternately stacked. The cavities 421, 422, 423, and 424 may be formed to have the same thickness. The cavities 421, 422, 423, and 424 may be provided such that an effective refractive index thereof is adjusted according to the central wavelengths of the unit filters 911, 912, 913, and 914. The cavities 421, 422, 423, and 424 may be provided such that a thickness thereof is adjusted. The polarizers 851, 852, 853, and 854 are provided on upper surfaces of the cavities 421, 422, 423, and 424.

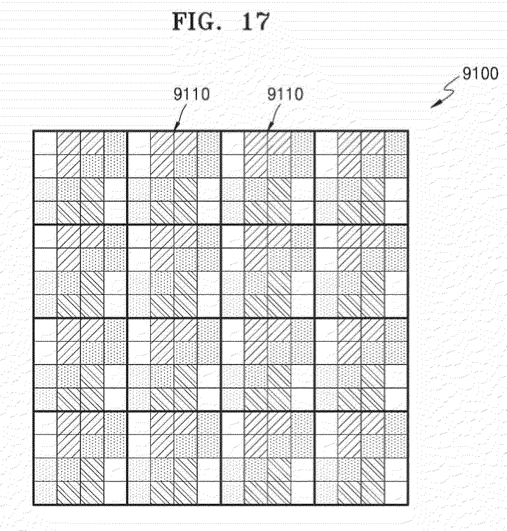

FIG. 17 is an example plan view of an optical filter 9100 that may be applied to the image sensor 1000 of FIG. 1.

Referring to FIG. 17, the optical filter 9100 may include a plurality of filter groups 9110 arranged in a two-dimensional form on the same plane. For example, each of the filter groups 9110 may be one of the optical filters 1100 to 1900 according to the example embodiments described above. Each of the filter groups 9110 includes a plurality of unit filters having different central wavelengths, and a description thereof is as described above, and thus will be omitted herein.

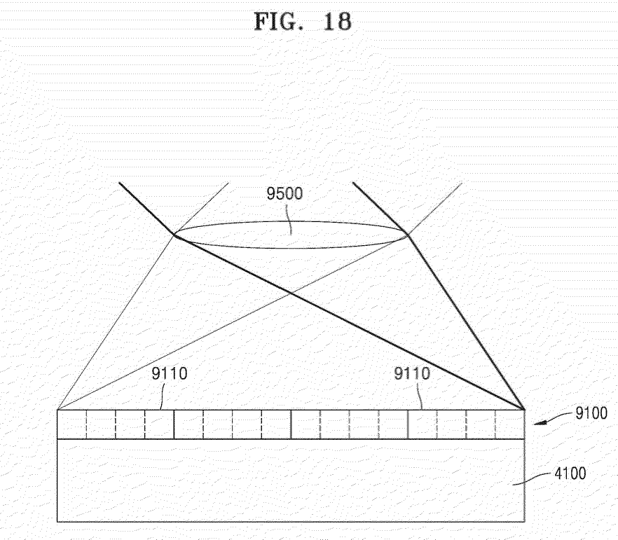

FIG. 18 illustrates an image sensor according to another example embodiment.

Referring to FIG. 18, an optical filter 9100 is provided on a pixel array 4100, and a single imaging lens 9500 is provided above the optical filter 9100. For example, the optical filter 9100 may be the optical filter 9100 including the plurality of filter groups 9110, shown in FIG. 17. As described above, the single imaging lens 9500 for forming an image of an object may be provided above the optical filter 9100, thereby implementing, as a simple optical system, a camera configured to obtain a spectral image and a polarization image.

The image sensor 1000 including an optical filter as describe above may be employed in various types of high-performance optical devices or high-performance electronic devices. Such an electronic device may include, for example, a smartphone, a mobile phone, a cellular phone, a personal digital assistant (PDA), a laptop, a PC, various types of portable devices, home appliances, a security camera, a medical camera, a car, an Internet of Things (IoT) device, and other mobile or non-mobile computing devices, but is not limited thereto.

The electronic device may further include a processor that controls the image sensor 1000, for example, an application processor (AP), in addition to the image sensor 1000, and may drive an operating system or an application program via the processor to control a plurality of hardware or software components, and perform various types of data processing and operations. The processor may further include a graphic processing unit (GPU) and/or an image signal processor. When the processor includes the image signal processor, an image acquired by an image sensor may be stored and/or output by using the processor.

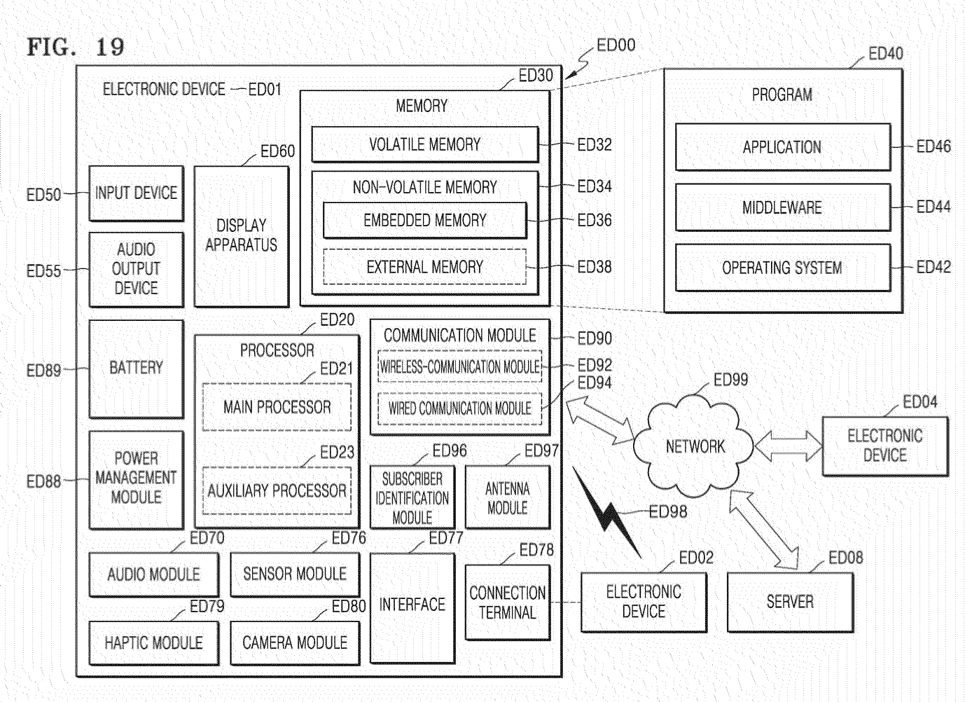

FIG. 19 is a block diagram illustrating an example of an electronic device ED01 including the image sensor 1000. Referring to FIG. 19, in a network environment ED00, the electronic device ED01 may communicate with another electronic device ED02 via a first network ED98 (e.g., a short-range wireless communication network or the like), or may communicate with another electronic device ED04 and/or a server ED08 via a second network ED99 (e.g., a long-range wireless communication network or the like). The electronic device ED01 may communicate with the electronic device ED04 via the server ED08. The electronic device ED01 may include a processor ED20, a memory ED30, an input device ED50, a sound output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. Some of these components (e.g., the display device ED60 and the like) may be omitted from the electronic device ED01, or other components may be added to the electronic device ED01. Some of these components may be implemented as one integrated circuit. For example, the sensor module ED76 (including a fingerprint sensor, an iris sensor, an illuminance sensor, and the like) may be embedded and implemented in the display device ED60 (including a display and the like). In addition, when the image sensor 1000 includes a spectral function, some functions (e.g., a color sensor and the illuminance sensor) of the sensor module ED76 may be implemented in the image sensor 1000, rather than in a separate sensor module.

The processor ED20 may execute software (e.g., a program ED40 or the like) to control one component or a plurality of components (e.g., hardware and software components, and the like) of the electronic device ED01 connected to the processor ED20, and perform various types of data processing or operations. As a part of data processing or operations, the processor ED20 may load, into a volatile memory ED32, commands and/or data received from other components (e.g., the sensor module ED76, the communication module ED90, and the like), process the commands and/or data stored in the volatile memory ED32, and store resultant data in a nonvolatile memory ED34. The processor ED20 may include a main processor ED21 (e.g., a central processing unit, an application processor, or the like), and an auxiliary processor ED23 (e.g., a graphical processing unit, an image signal processor, a sensor hub processor, a communication processor, or the like) that may operate independently of or together with the main processor ED21. The auxiliary processor ED23 may use less power than the main processor ED21, and perform a particularized function.

The auxiliary processor ED23 may control functions and/or states related to some (e.g., the display device ED60, the sensor module ED76, the communication module ED90, and the like) of the components of the electronic device ED01, on behalf of the main processor ED21 while the main processor ED21 is in an inactive state (e.g., a sleep state), or together with the main processor ED21 while the main processor ED21 is in an active state (e.g., an application execution state). The auxiliary processor ED23 (e.g., the image signal processor, the communication processor, or the like) may be implemented as a part of other functionally related components (e.g., the camera module ED80, the communication module ED90, and the like).

The memory ED30 may store various types of data needed by the components of the electronic device ED01 (e.g., the processor ED20, the sensor module ED76, and the like). The data may include, for example, software (e.g., the program ED40 and the like), and input data and/or output data for a command related thereto. The memory ED30 may include the volatile memory ED32 and/or the nonvolatile memory ED34. The nonvolatile memory ED34 may include an internal memory ED36 fixedly mounted within the electronic device ED01, and a removable external memory ED38.

The program ED40 may be stored as software in the memory ED30, and may include an operating system ED42, middleware ED44 and/or an application ED46.

The input device ED50 may receive, from the outside (e.g., a user or the like) of the electronic device ED01, commands and/or data to be used for the components of the electronic device ED01 (e.g., the processor ED20 and the like). The input device ED50 may include a microphone, a mouse, a keyboard, and/or a digital pen (e.g., a stylus pen or the like).

The sound output device ED55 may output a sound signal to the outside of the electronic device ED01. The sound output device ED55 may include a speaker and/or a receiver. The speaker may be used commonly for multimedia reproduction or recording reproduction, and the receiver may be used to receive an incoming phone call. The receiver may be integrated as a part of the speaker, or may be implemented as an independent separate device.

The display device ED60 may visually provide information to the outside of the electronic device ED01. The display device ED60 may include a display, a hologram device, or a projector and a control circuit for controlling the corresponding device. The display device ED60 may include a touch circuitry configured to detect a touch, and/or a sensor circuit (e.g., a pressure sensor or the like) configured to measure the intensity of a force generated by the touch.

The audio module ED70 may convert a sound into an electrical signal, or conversely, may convert an electrical signal into a sound. The audio module ED70 may acquire a sound via the input device ED50, or may output a sound via the sound output device ED55, and/or a speaker and/or headphones of another electronic device (e.g., the electronic device ED02 or the like) directly or wirelessly connected to the electronic device ED01.

The sensor module ED76 may detect an operation state (e.g., power, temperature, and the like) of the electronic device ED01, or an external environmental state (e.g., a user state or the like), and may generate an electrical signal and/or a data value corresponding to the detected state. The sensor module ED76 may include a gesture sensor, a gyro sensor, a pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface ED77 may support one designated protocol or a plurality of designated protocols that may be used to directly or wirelessly connect the electronic device ED01 to the other electronic device (e.g., the electronic device ED02 or the like). The interface ED77 may include a high definition multimedia interface (HDMI), a universal serial bus (USB) interface, an SD card interface, and/or an audio interface.

A connection terminal ED78 may include a connector through which the electronic device ED01 may be physically connected to the other electronic device (e.g., the electronic device ED02 or the like). The connection terminal ED78 may include an HDMI connector, a USB connector, an SD card connector, and/or an audio connector (e.g., a headphone connector or the like).

The haptic module ED79 may convert an electrical signal into a mechanical stimulus (e.g., vibration, movement, or the like) or an electrical stimulus that may be perceived by a user through tactile or kinesthetic sense. The haptic module ED79 may include a motor, a piezoelectric element, and/or an electrical stimulation device.

The camera module ED80 may capture a still image and a moving image. The camera module ED80 may include a lens assembly including one lens or a plurality of lenses, the image sensor 1000 of FIG. 1, image signal processors, and/or flashes. The lens assembly included in the camera module ED80 may collect light emitted from a subject from which an image is to be captured.

The power management module ED88 may manage power supplied to the electronic device ED01. The power management module ED88 may be implemented as a part of a power management integrated circuit (PMIC).

The battery ED89 may supply power to the components of the electronic device ED01. The battery ED89 may include a non-rechargeable primary cell, a rechargeable secondary cell, and/or a fuel cell.

The communication module ED90 may support establishment of a direct (wired) communication channel and/or a wireless communication channel between the electronic device ED01 and the other electronic devices (e.g., the electronic device ED02 and the electronic device ED04) and the server ED08, and performance of communication via the established communication channels. The communication module ED90 may include one communication processor or a plurality of communication processors that operate independently of the processor ED20 (e.g., an application processor or the like), and support direct communication and/or wireless communication. The communication module ED90 may include a wireless communication module ED92 (e.g., a cellular communication module, a short-range wireless communication module, a global navigation satellite system (GNSS) communication module, or the like) and/or a wired communication module ED94 (e.g., a local area network (LAN) communication module, a power line communication module, or the like). From among these communication modules, the corresponding communication module may communicate with the other electronic device via the first network ED98 (e.g., a short-range communication network such as Bluetooth, WiFi Direct, or Infrared Data Association (IrDA)) or the second network ED99 (e.g., a long-range communication network such as a cellular network, Internet, or a computer network (LAN, WAN, or the like)). Such several types of communication modules may be integrated into one component (e.g., a single chip, or the like), or may be implemented as a plurality of components (e.g., a plurality of chips) separate from each other. The wireless communication module ED92 may identify and authenticate the electronic device ED01 within a communication network, such as the first network ED98 and the second network ED99, by using subscriber information (e.g., International Mobile subscriber identity (IMSI) or the like) stored in the subscriber identification module ED96.

The antenna module ED97 may transmit or receive a signal and/or power to or from the outside (e.g., the other electronic device or the like). An antenna may include a radiator having a conductive pattern formed on a substrate (e.g., a PCB or the like). The antenna module ED97 may include one antenna or a plurality of antennas. When a plurality of antennas are included, an antenna appropriate for a communication method used in a communication network, such as the first network ED98 and/or the second network ED99, may be selected from among the plurality of antennas by the communication module ED90. A signal and/or power may be transmitted or received between the communication module ED90 and the other electronic device via the selected antenna. In addition to the antenna, other parts (e.g., an RFIC and the like) may be included as a part of the antenna module ED97.

Some of the components may be connected to each other and exchange a signal (e.g., a command, data, or the like) via a communication method (e.g., a bus, general purpose input and output (GPIO), a serial peripheral interface (SPI), a mobile industry processor interface (MIPI), or the like) between peripheral devices.

The command or data may be transmitted or received between the electronic device ED01 and the external electronic device ED04 via the server ED08 connected to the second network ED99. The other electronic devices ED02 and ED04 may be the same or different kinds of devices as or than the electronic device ED01. All or some of operations executed in the electronic device ED01 may be executed in one device or a plurality of devices from among the other electronic devices ED02, ED04, and ED08. For example, when the electronic device ED01 needs to perform a function or service, the electronic device ED01 may request one electronic device or a plurality of other electronic devices to perform a part or all of the function or service, instead of executing the function or service. The one electronic device or the plurality of other electronic devices, which receive the request, may execute an additional function or service related to the request, and may transmit the result of the execution to the electronic device ED01. Accordingly, cloud computing, distributed computing, and/or client-server computing technologies may be used.

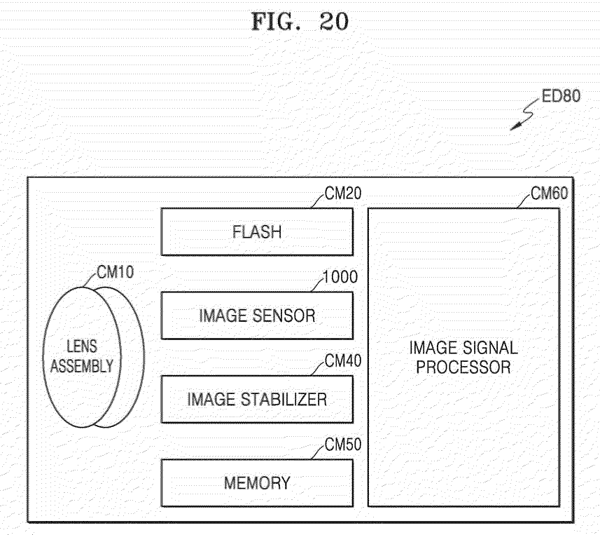

FIG. 20 is a block diagram illustrating the camera module ED80 of FIG. 19. Referring to FIG. 20, the camera module ED80 may include a lens assembly CM10, a flash CM20, an image sensor 1000 (e.g., the image sensor 1000 of FIG. 1 or the like), an image stabilizer CM40, a memory CM50 (e.g., a buffer memory or the like), and/or an image signal processor CM60. The lens assembly CM10 may collect light emitted from a subject from which an image is to be captured. The camera module ED80 may also include a plurality of lens assemblies CM10. In this case, the camera module ED80 may be a dual camera, a 360-degree camera, or a spherical camera. Some of the plurality of lens assemblies CM10 may have the same lens attributes (e.g., an angle of view, a focal length, an auto focus, an F number, optical zoom, and the like) or different lens attributes. The lens assembly CM10 may include a wide-angle lens or a telephoto lens.

The flash CM20 may emit light used to intensify light emitted or reflected from a subject. The flash CM20 may include one light emitting diode or a plurality of light emitting diodes (LEDs) (e.g., a red-green-blue (RGB) LED, a white LED, an infrared LED, an ultraviolet LED, and the like), and/or a xenon lamp. The image sensor 1000 may be an image sensor as described above with reference to FIG. 1, and may acquire an image corresponding to the subject by converting, into an electrical signal, light emitted or reflected from the subject and transmitted through the lens assembly CM10. The image sensor 1000 may include one sensor or a plurality of sensors selected from image sensors having different attributes, such as an RGB sensor, a black and white (BW) sensor, an IR sensor, and a UV sensor. The respective sensors included in the image sensor 1000 may be implemented as a charged-coupled device (CCD) sensor and/or a complementary metal oxide semiconductor (CMOS) sensor.

The image stabilizer CM40 may respond to the movement of the camera module ED80 or the electronic device ED01 including the same to move one lens or a plurality of lenses included in the lens assembly CM10, or the image sensor 1000 in a particular direction, or control operation characteristics of the image sensor 1000 (e.g., adjustment of a read-out timing and the like), thereby compensating for negative effects due to the movement. The image stabilizer CM40 may detect the movement of the camera module ED80 or the electronic device ED01 by using a gyro sensor (not shown) or an acceleration sensor (not shown) arranged inside or outside the camera module ED80. The image stabilizer CM40 may be implemented optically.

The memory CM50 may store, for next image processing work, some or all data of images acquired via the image sensor 1000. For example, when a plurality of images are acquired at a high speed, the plurality of images may be used to store acquired original data (e.g., Bayer-patterned data, high-resolution data, and the like) in the memory CM50, display only a low-resolution image, and then transmit original data of an image selected (e.g., selected by a user or the like) to the image signal processor CM60. The memory CM50 may be integrated into the memory ED30 of the electronic device ED01, or may be configured as a separate memory that operates independently.

The image signal processor CM60 may perform various types of image processing on the images acquired via the image sensor 1000 or the image data stored in the memory CM50. The various types of image processing may include depth map generation, three-dimensional modeling, panoramic generation, feature point extraction, image synthesis, and/or image compensation (e.g., noise reduction, resolution adjustment, brightness adjustment, blurring, sharpening, softening, or the like). The image signal processor CM60 may perform control (e.g., exposure time control, or read-out timing control, or the like) on the components (e.g., the image sensor 1000 and the like) included in the camera module ED80. An image processed by the image signal processor CM60 may, for further processing, be stored again in the memory CM50 or provided to an external component (e.g., the memory ED30, the display device ED60, the electronic device ED02, the electronic device ED04, the server ED08, or the like) of the camera module ED80. The image signal processor CM60 may be integrated into the processor ED20, or may be configured as a separate processor that operates independently of the processor ED20. When the image signal processor CM60 is configured as a processor separate from the processor ED20, an image processed by the image signal processor CM60 may undergo additional image processing via the processor ED20, and then may be displayed via the display device ED60.

The electronic device ED01 may include a plurality of camera modules ED80 having different attributes orfunctions. In this case, one of the plurality of camera modules ED80 may be a wide-angle camera, and the other one may be a telephoto camera. Similarly, one of the plurality of camera modules ED80 may be a front camera, and the other one may be a rear camera.

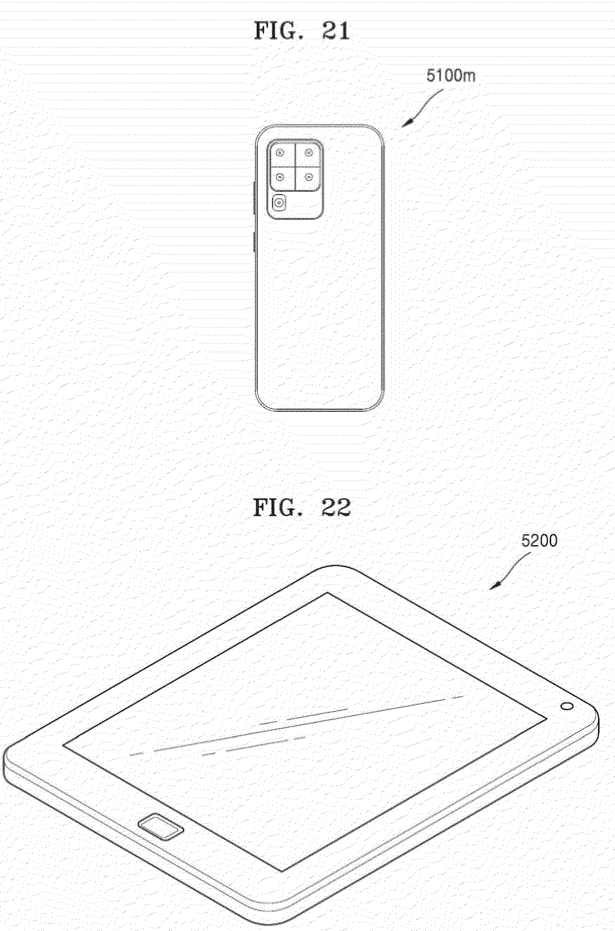

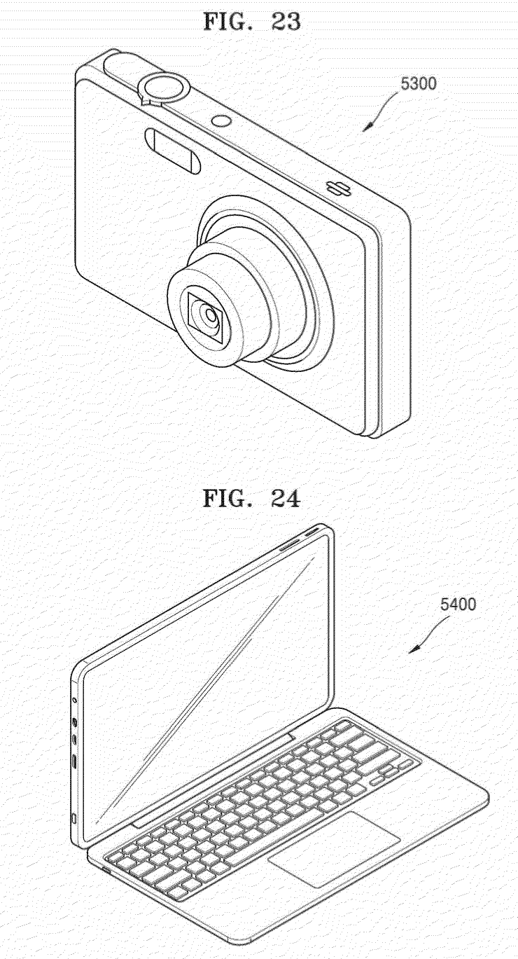

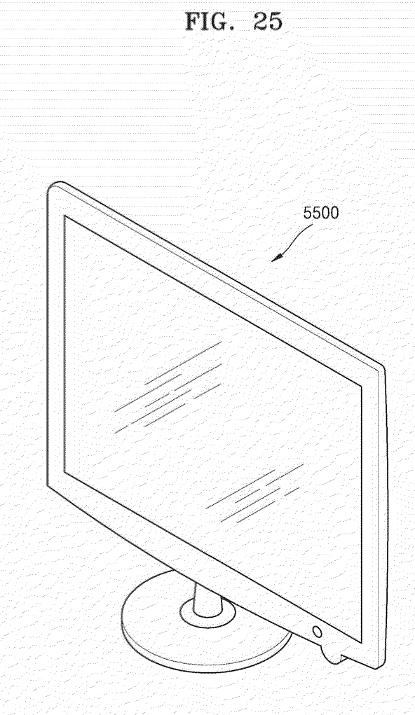

The image sensor 1000 according to the embodiments may be applied to a mobile phone or smartphone 5100m shown in FIG. 21, a tablet or smart tablet 5200 shown in FIG. 22, a digital camera or camcorder 5300 shown in FIG. 23, a notebook computer 5400 shown in FIG. 24, or a television or smart television 5500 shown in FIG. 25. For example, the smartphone 5100m or the smart tablet 5200 may include a plurality of high-resolution cameras each having a high-resolution image sensor mounted thereon. The high-resolution cameras may be used to extract depth information of subjects within an image, adjust out-focusing of the image, or automatically identify the subjects within the image.

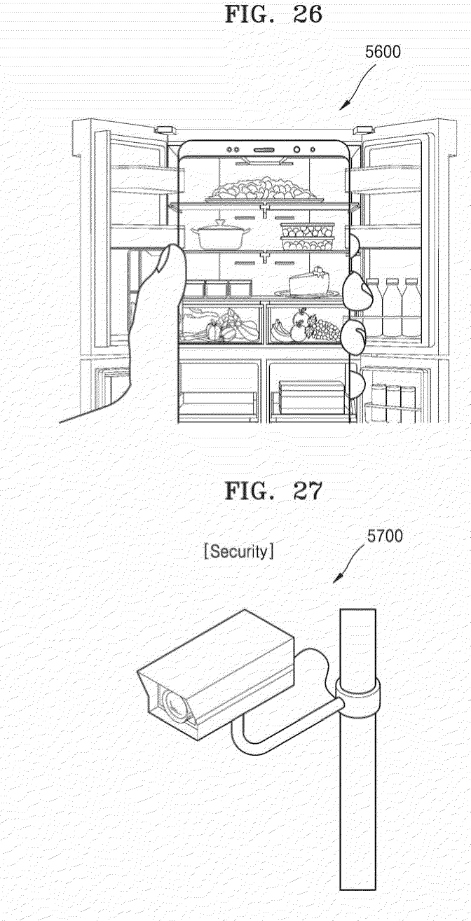

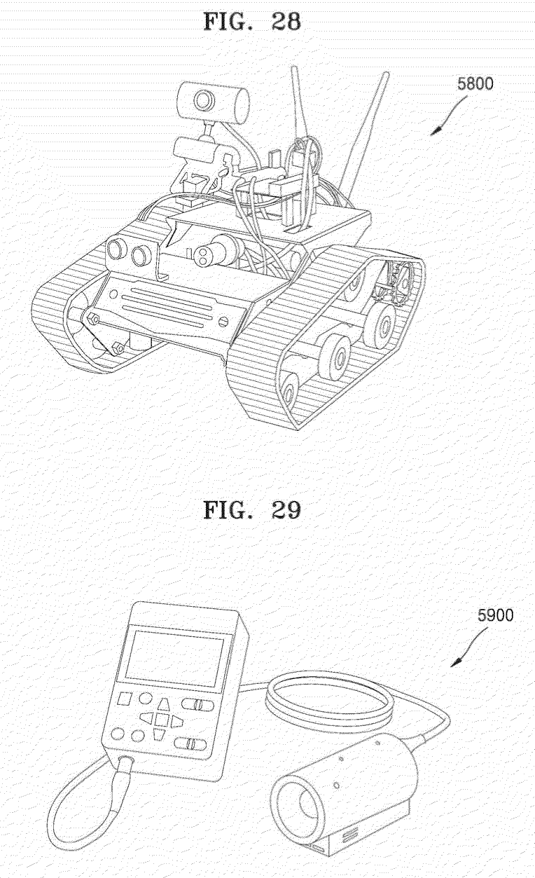

In addition, the image sensor 1000 may be applied to a smart refrigerator 5600 shown in FIG. 26, a security camera 5700 shown in FIG. 27, a robot 5800 shown in FIG. 28, a medical camera 5900 shown in FIG. 29, and the like. For example, the smart refrigerator 5600 may use an image sensor to automatically recognize food within the smart refrigerator 5600, and inform a user via a smartphone of whether or not particular food is present, types of food that are put into or taken out of the smart refrigerator 5600, and the like. The security camera 5700 may provide an ultra-high resolution image, and may allow an object or a person within an image to be recognized even in a dark environment by using high sensitivity. The robot 5800 may be put into a disaster or industrial site that may not be directly accessed by a person and provide a high-resolution image. The medical camera 5900 may provide a high-resolution image for diagnosis or surgery, and may dynamically adjust a field of view.

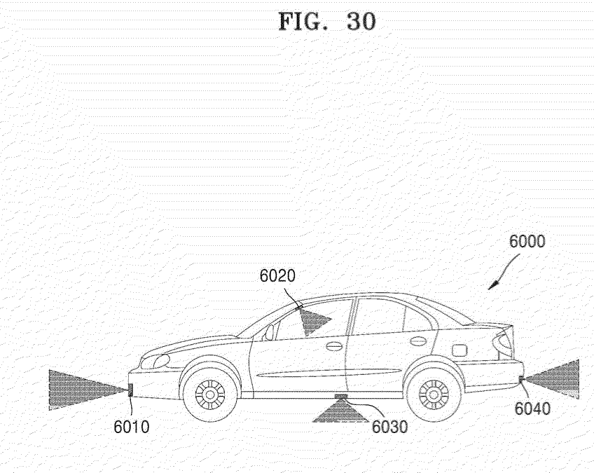

In addition, the image sensor 1000 may be applied to a vehicle 6000 as shown in FIG. 30. The vehicle 6000 may include a plurality of vehicle cameras 6010, 6020, 6030, and 6040 arranged at various locations. The vehicle cameras 6010, 6020, 6030, and 6040 may each include an image sensor according to an embodiment. The vehicle 6000 may use the plurality of vehicle cameras 6010, 6020, 6030, and 6040 to provide a driver with various types of information about the inside or periphery of the vehicle 6000 and provide information needed for autonomous driving by automatically recognizing an object or a person within an image.

According to the example embodiments described above, an image sensor may include an optical filter configured to perform a spectral function and a polarization function to be implemented to obtain both a spectral image and a polarized image.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. An optical filter comprising:
a spectral filter; and
a polarizing filter provided on the same plane as the spectral filter,
wherein the spectral filter comprises a plurality of spectral unit filters having different central wavelengths, and
wherein the polarizing filter comprises a plurality of polarization unit filters having different central wavelengths.

2. The optical filter of claim 1, wherein the spectral filter comprises four or more spectral unit filters having different central wavelengths.

3. The optical filter of claim 1, wherein the spectral unit filters each comprise a lower metal reflector, a first cavity provided on the lower metal reflector, and an upper metal reflector provided on the first cavity.

4. The optical filter of claim 3, wherein an effective refractive index or a thickness of the first cavity is adjusted based on the central wavelength of each of the spectral unit filters.

5. The optical filter of claim 3, wherein the spectral unit filters each further comprise a lower dielectric layer provided on the lower metal reflector.

6. The optical filter of claim 5, wherein the spectral unit filters each further comprise an upper dielectric layer provided on the upper metal reflector.

7. The optical filter of claim 6, wherein an effective refractive index or a thickness of the lower dielectric layer and the upper dielectric layer is adjusted based on the central wavelength of each of the spectral unit filters.

8. The optical filter of claim 3, wherein the polarization unit filters each comprise the lower metal reflector, a second cavity provided on the lower metal reflector, and a polarizer provided on the second cavity.

9. The optical filter of claim 8, wherein the polarization unit filters each further comprise the lower dielectric layer provided on the lower metal reflector.

10. The optical filter of claim 8, wherein the polarizer comprises a metal grid.

11. The optical filter of claim 10, wherein the upper metal reflector comprises a metal pattern having the same thickness as the metal grid.

12. The optical filter of claim 1, wherein the spectral unit filters each comprise a lower Bragg reflective layer, a first cavity provided on the lower Bragg reflective layer, and an upper Bragg reflective layer provided on the first cavity.

13. The optical filter of claim 12, wherein the polarization unit filters each comprise the lower Bragg reflective layer, a second cavity provided on the lower Bragg reflective layer, and a polarizer provided on the second cavity.

14. The optical filter of claim 12, wherein the polarizer comprises a metal grid.

15. The optical filter of claim 1, wherein the spectral unit filters each comprise a Bragg reflective layer, a first cavity provided on the Bragg reflective layer, and a metal reflector provided on the first cavity, and
wherein the polarization unit filters each comprise the Bragg reflective layer, a second cavity provided on the Bragg reflective layer, and a polarizer provided on the second cavity.

16. The optical filter of claim 15, wherein the metal reflector comprises a metal pattern, and
wherein the polarizer comprises a metal grid.

17. The optical filter of claim 16, wherein the metal reflector and the polarizer have the same thickness.

18. The optical filter of claim 1, further comprising a reference filter provided on the same plane as the spectral filter and the polarizing filter.

19. The optical filter of claim 18, wherein the reference filter comprises at least one of a blank filter and a dark filter.

20. An optical filter comprising:
a plurality of unit filters provided on the same plane and having different central wavelengths,
wherein each of the plurality of unit filters comprises:
a metal reflector; a cavity provided on the metal reflector; and
a polarizer provided on the cavity.

21. The optical filter of claim 20, wherein the polarizer comprises a metal grid.

22. An optical filter comprising:
a plurality of unit filters provided on the same plane and having different central wavelengths,
wherein each of the plurality of unit filters comprises:
a Bragg reflective layer;
a cavity provided on the Bragg reflective layer; and
a polarizer provided on the cavity.

23. The optical filter of claim 22, wherein the polarizer comprises a metal grid.

24. An image sensor comprising:
a pixel array comprising a plurality of pixels; and
an optical filter provided on the pixel array.

25. The image sensor of claim 24, further comprising a single imaging lens provided above the optical filter.

26. The image sensor of claim 24, further comprising a timing controller, a row decoder, and an output circuit.

27. An electronic device comprising:
an image sensor comprising:
a pixel array comprising a plurality of pixels; and
an optical filter provided on the pixel array,
wherein the optical filter comprises:
a spectral filter; and
a polarizing filter provided on the same plane as the spectral filter,
wherein the spectral filter comprises a plurality of spectral unit filters having different central wavelengths, and
wherein the polarizing filter comprises a plurality of polarization unit filters having different central wavelengths.

28. The electronic device of claim 27, wherein the electronic device comprises a mobile phone, a smart phone, a tablet, a smart tablet, a digital camera, a camcorder, a notebook computer, a television, a smart television, a smart refrigerator, a security camera, a robot, or a medical camera.
